(19) United States
(12) Patent Application Publication
(10) Pub. No.: US 2009/0154109 A1
(43) Pub. Date: Jun. 18, 2009

(54) HEAT SINK ASSEMBLY

(75) Inventors: MING-KE CHEN, Shenzhen (CN); KE SUN, Shenzhen (CN); ZHEN-XING YE, Shenzhen (CN); XIAO-ZHU CHEN, Shenzhen (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/967,056

(22) Filed: Dec. 29, 2007

(30) Foreign Application Priority Data
Dec. 14, 2007 (CN) 200710203090.4

(51) Int. Cl. H05K 7/20

(52) U.S. Cl. 361/709

(57) ABSTRACT

A heat sink assembly includes a heat sink and a clip for securing the heat sink to a circuit board with a pair of securing members mounted thereon. The clip is a bent resilient wire including a positioning portion disposed on the heat sink and a pair of arms extending from opposite ends of the positioning portion. Each arm includes an operation portion suspended above the heat sink and a hook connecting with the operation portion. The securing members are located at opposite lateral sides of the electronic component respectively. The two hooks are configured for engaging with the securing members, correspondingly.

### BACKGROUND OF THE INVENTION

1. Field of the Invention

The present invention relates to a heat sink assembly, and more particularly to a heat sink assembly with a heat sink and a clip which can readily and securely attach the heat sink to an electronic device.

2. Description of Related Art

A heat sink is usually placed in thermal contact with an electronic package such as a south bridge or north bridge chipset, and transfers heat through conduction away from the electronic package so as to prevent over-heating of the electronic package. Usually, a plurality of securing members is mounted on a circuit board and a heat sink is secured to an electronic package by using a clip engaged with the corresponding securing members.

Securing members are generally arranged as near as possible to a corresponding electronic package to conserve space for more densely mounting components on the circuit board. When a heat sink is mounted to or detached from the circuit board, the clip is manually operated by a user. However it may be very inconvenient to manipulate the clip, especially when the electronic package is arranged nearby other electronic components of the circuit board.

What is needed is to provide a heat sink assembly with a heat sink and a clip which can be conveniently operated to secure the heat sink to a circuit board even though the circuit board is crowded with a plurality of electronic components.

### SUMMARY OF THE INVENTION

An exemplary heat sink assembly includes a heat sink and a clip for securing the heat sink to a circuit board with a pair of securing members mounted thereon. The clip is a bent resilient wire including a positioning portion disposed on the heat sink and a pair of arms extending from opposite ends of the positioning portion. Each arm includes an operation portion suspended above the heat sink and a hook connecting with the operation portion. The securing members are located at opposite lateral sides of the electronic component respectively. The two hooks are configured for engaging with the securing members, correspondingly.

Other advantages and novel features of the invention will become more apparent from the following detailed description when taken in conjunction with the accompanying drawings, in which:

### BRIEF DESCRIPTION OF THE DRAWINGS

FIG. 1 is an exploded, isometric view of a heat sink assembly with a circuit board in accordance with a preferred embodiment of the present invention; and

FIG. 2 is an assembled, isometric view of FIG. 1.

### DETAILED DESCRIPTION OF THE EMBODIMENT

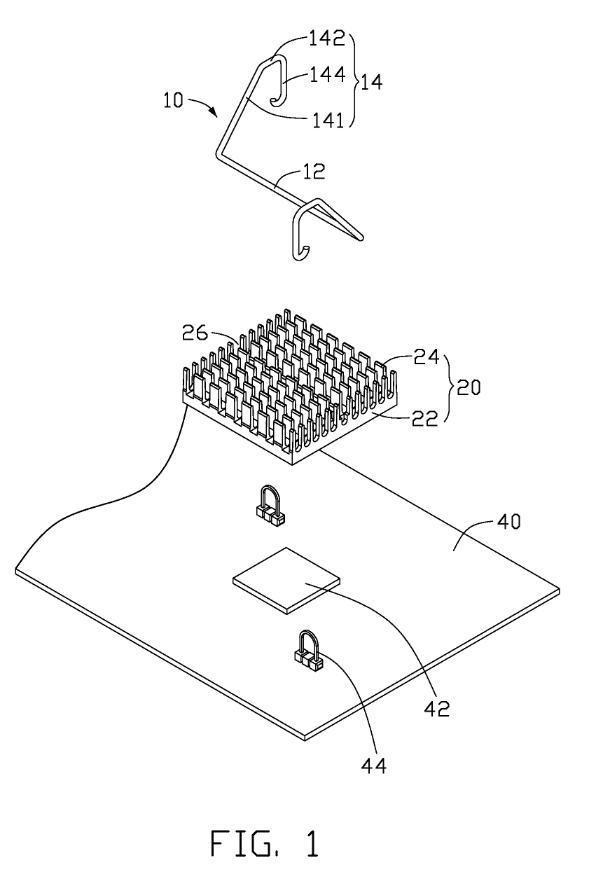

Referring to FIG. 1, a heat sink assembly in accordance with an embodiment of present invention includes a heat sink 20, a clip 10 used for securing the heat sink 20 to a circuit board 40 including an electronic component 42 mounted thereon, and a pair of n-shaped securing members 44 mounted on the circuit board 40 at opposite lateral sides of the electronic component 42 respectively.

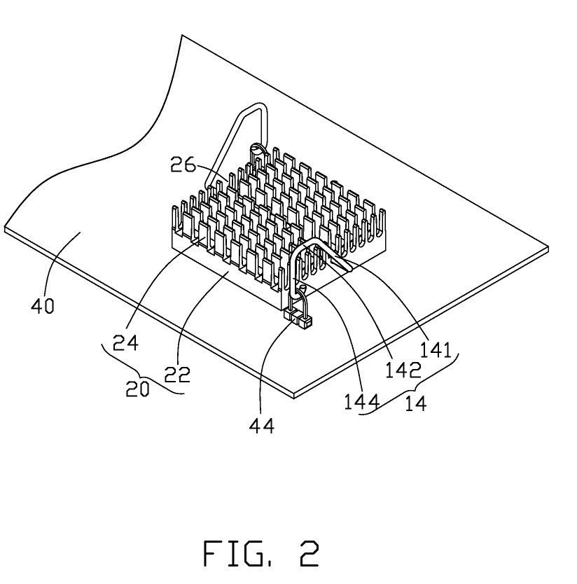

Referring also to FIG. 2, the clip 10 is a bent resilient wire including a pole-like positioning portion 12 and a pair of arms 14. Each arm 14 includes a deformable portion 141 slantingly extending upwards from an end of the positioning portion 12, an operation portion 142 horizontally extending from a distal end of the deformable portion 141 and a J-shaped hook 144 extending downward from a distal end of the operation portion 142. The arms 14 are formed in planes perpendicular to the positioning portion 12 and are arranged at two sides of the positioning portion 12 respectively. The operation portions 142 extend in opposite directions away from the positioning portion 12.

The heat sink 20 includes a base 22 having a bottom face thermally contacting with the electronic component 42, and a plurality of fins 24 extending perpendicularly upwards from a top face of the base 22. A locating grooving 26 for receiving the positioning portion 12 of the clip 10 is transversely defined across a middle of the heat sink 20.

In use, The heat sink 20 is put on the electronic component 42 of the circuit board 40 with diagonal angle of the heat sink 20 being adjacent to the two securing members 44 correspondingly. Then the positioning portion 12 of the clip 10 is retained in the locating groove 26 of the heat sink 20 with the operation portions 142 suspended above the heat sink 20. The operation portions 142 are pressed downwards to deform the deformable portions 141 and then the hooks 144 catch the securing portions 44, the heat sink 20 is thus secured to the circuit board 40.

To detach the heat sink 20 from the circuit board 40, the operation portions 144 are pressed to deform the deformable portions 141 to disengage the hooks 144 from the corresponding securing members 44 and then the heat sink 20 made be removed from the circuit board 40.

It is believed that the present embodiment and its advantages will be understood from the foregoing description, and it will be apparent that various changes may be made thereto without departing from the spirit and scope of the invention or sacrificing all of its material advantages, the example hereinbefore described merely being a preferred or exemplary embodiment.

What is claimed is:

1. A heat sink assembly for cooling an electronic component mounted on a circuit board thereon, the heat sink assembly comprising:
a heat sink thermally contacted with the electronic component;
a clip securing the heat sink to the circuit board, the clip comprising a positioning portion disposed on the heat sink and a pair of resilient arms extending from opposite ends of the positioning portion, each arm comprising an operation portion suspended above the heat sink and a hook connecting with the operation portion; and
a pair of securing members mounted on the circuit board at opposite lateral sides of the electronic component respectively and configured for engaging with the corresponding hooks of the clip.

2. The heat sink assembly as claimed in claim 1, wherein each arm comprises a deformable portion slantingly extending upwards from a free end of the positioning portion, the operation portions extend horizontally from the distal end of the corresponding deformable portion and the hooks extend downward from the distal end of the corresponding operation portion.

3. The heat sink assembly as claimed in claim 2, wherein the positioning portions are pole-like, and the arms are formed in planes vertical to the positioning portion.

4. The heat sink assembly as claimed in claim 3, wherein the two securing members are arranged adjacent to a pair of diagonal angles of the heat sink correspondingly, the arms are arranged at two sides of the position portion respectively with the two operation portions extending in opposite directions away from the positioning portion.

5. The heat sink assembly as claimed in claim 1, the heat sink is located on the circuit board with diagonal angle of the heat sink being adjacent to the two securing members correspondingly.

6. The heat sink assembly as claimed in claim 1, wherein the clip is a bent resilient wire.

7. The heat sink assembly as claimed in claim 2, wherein the securing members are n-shaped, the hooks are J-shaped corresponding to engaging with the securing members.
